(19) United States
(12) Patent Application Publication
(10) Pub. No.: US 2013/0002235 A1
(43) Pub. Date: Jan. 3, 2013

(54) TEST BOX FOR ELECTROSTATIC GENERATORS

(75) Inventor: XIAO-LIAN HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/206,534

(22) Filed: Aug. 10, 2011

(30) Foreign Application Priority Data
Jun. 30, 2011 (CN) 201110181612.1

(51) Int. Cl. G01R 13/20; G01R 1/04

(52) U.S. Cl. 324/121 R; 324/156

(57) ABSTRACT

A test box for electrostatic generators includes a housing and an electrostatic target. The housing is structured to define a shielded space for receiving a measuring device and is further structured to prevent outside electromagnetic radiation from entering the shielded space. The electrostatic target is mounted on an outside surface of the housing and electrically connected to the measuring device. Electrostatic signals emitted from the electrostatic generators are received and transmitted to the measuring device by the electrostatic target, thereby displaying waveforms of the electrostatic signals using the measuring device.

### BACKGROUND

1. Technical Field

The present disclosure relates to test boxes for electronic devices, and particularly to test box for electrostatic generators.

2. Description of Related Art

In quality tests for electrostatic generators (e.g., electrostatic guns), oscilloscopes are often used to display waveforms of electronic signals generated by the electrostatic generators, such that users can determine whether the electrostatic generators work normally according to the waveforms. However, when the electrostatic generators work, they may generate unwanted electromagnetic radiation. The electromagnetic radiation may adversely affect display effects of the oscilloscopes. Therefore, a test box for electrostatic generators, which can protect the oscilloscopes from electromagnetic radiation of the electrostatic generators, is desired.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a schematic view of a test box for electrostatic generators, according to an exemplary embodiment.

FIG. 2 is similar to FIG. 1, but viewed from another angle.

### DETAILED DESCRIPTION

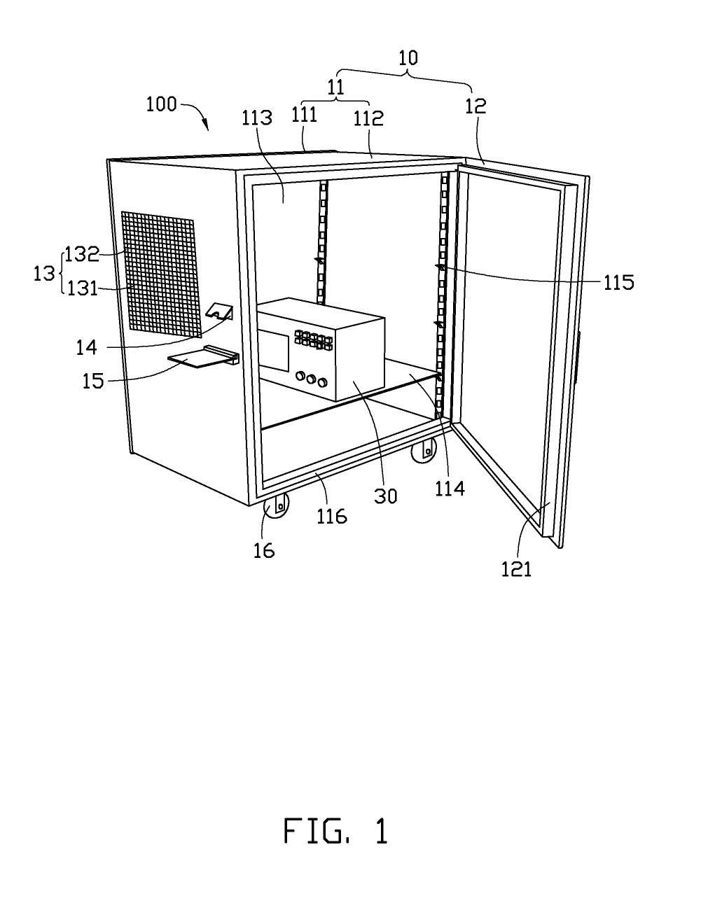

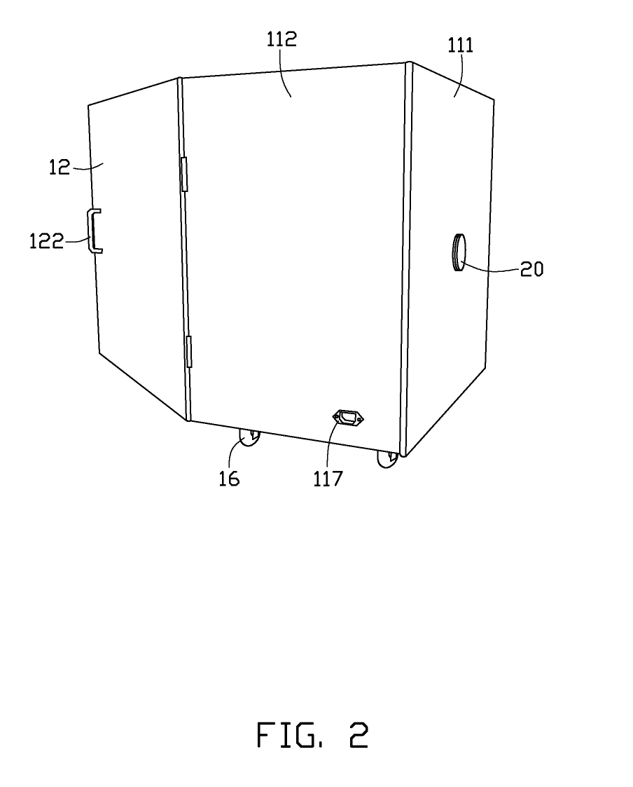

FIG. 1 and FIG. 2 show a test box 100 for electrostatic generators, according to an exemplary embodiment. The test box 100 includes a housing 10 and an electrostatic target 20. The test box 100 can receive measuring devices for testing quality of electrostatic generators (not shown), such as electrostatic guns. In this embodiment, an oscilloscope 30 is received in the test box 100 to test the quality of the electrostatic generators.

The housing 10 includes a main body 11 and a cover board 12, which are both made of electromagnetic shielding materials, such as metal. The main body 11 includes a substantially rectangular target panel 111 and a substantially rectangular frame 112. The electrostatic gasket 20 is mounted on an outer surface of the target panel 111. The frame 112 includes four substantially rectangular sidewalls (not labeled). The four sidewalls are respectively perpendicularly connected to four sides of the same surface of the target panel 111, such that the target panel 111 and the frame 112 cooperatively define a substantially cuboid-shaped shielded space 113. The oscilloscope 30 is received in the shielded space 113 and is electrically connected to the electrostatic target 20. In this embodiment, the housing 10 further includes a shelf 114 for holding the oscilloscope 30.

A number of protrusions 115 are formed on inner surfaces of two opposite ones of the sidewalls for holding the shelf 114. The protrusions 115 are positioned at different heights, such that the shelf 114 can be placed at different levels on the protrusions 115 to adjust heights of the shelf 114 and the oscilloscope 30 that is placed on the shelf 114.

The cover board 12 is rotatably assembled to one sidewall of the frame 112. A rotation of the cover board 12 can open and close the shielded space 113. When the cover board 12 is closed, the main body 11 and the cover board 12 prevent outside electromagnetic radiation from entering the shielded space 113.

In this embodiment, the housing 10 further includes a first gasket 116 mounted on a circle of an inner surface of the frame 112, and a second gasket 121 mounted on a surface of the cover board 12 positioned towards the main body 11. The first gasket 116 is made of elastic materials, such as rubber, and the second gasket 121 is made of elastic electromagnetic shielding materials, such as electromagnetic absorptive foam. Shapes and sizes of the first gasket 116 and the second gasket 121 are corresponding to each other. When the shielded space 113 is closed by the cover board 12, the first gasket 116 and the second gasket 121 contact each other, such that the impact generated between the frame 112 and the cover board 12 is decreased. The second gasket 121 can further prevent outside electromagnetic radiation from entering the shielded space 113 through an aperture between the cover board 12 and the frame 11. Furthermore, the first gasket 116 can define a slot (not shown) corresponding to the second gasket 121 for engaging with the second gasket 121.

The main body 10 further includes a detection member 13, a connection hole 14, and a manual operation holder 15. The detection member 13 is formed in a sidewall of the frame 112 that is positioned towards a display (not labeled) of the oscilloscope 30. The detection member 13 includes a metal shield net 131 and a transparent view window 132. The view window 132 engages with a hole (not labeled) defined in the sidewall of the frame 112, and the shield net 131 is mounted on the view window 132. In this way, images displayed by the oscilloscope 30 can be viewed through meshes of the shield net 131 and the view window 132, and the shield net 131 can prevent outside electromagnetic radiation from entering the shielded space 113 through the view window 132. The connection hole 14 can be defined in the target panel 111 or the frame 112. The manual operation holder 15 is a planar board perpendicularly connected to a sidewall of the frame 112. In this embodiment, the detection member 13, the connection hole 14, and the manual operation holder 15 are all formed in the same sidewall of the frame 122. The connection hole 14 and the manual operation holder 15 are positioned adjacent to the detection member 13. A manual operation device (not shown) for the oscilloscope 30, such as a mouse, can be placed on the manual operation holder 15, and is connected to the oscilloscope 30 by a cable (not shown) passing through the connection hole 14.

In use, the shielded space 113 is closed by the cover board 12, and a tested electrostatic generator (not shown) emits electrostatic signals towards the electrostatic target 20. The electrostatic target 20 receives the electrostatic signals from the tested electrostatic generator and transmits the electrostatic signals to the oscilloscope 30. Upon receiving the electrostatic signals, the oscilloscope 30 displays waveforms of the electrostatic signals. Users can view the waveforms displayed by the oscilloscope 30 through the detection member 13, and determine whether the tested electrostatic generator works normally according to the waveforms. Because electromagnetic radiation of the tested electrostatic generator and other outside electromagnetic radiation are prevented from entering the shielded space 113 by the housing 10, the oscilloscope 30 can be protected from electromagnetic radiation and thus display the waveforms of the electrostatic signals generated by the tested electrostatic generator precisely. Furthermore, in the test process, users can operate the oscilloscope 30 using a manual operation device (e.g., a mouse) placed on the manual operation holder 15 and connected to the oscilloscope 30 through a cable passing through the connection hole 14.

The test box 100 can further include a power supply interface 117 mounted on the main body 11 and electrically connected to the oscilloscope 30, a handle 122 mounted on an outer surface of the cover board 12, and a plurality of wheels 16 rotatably mounted on a bottom of the main body 11. In use, a power supply (not shown) for the oscilloscope 30 can be connected to the oscilloscope 30 through the power supply interface 117. The handle 122 can facilitate operating the cover board 12. The wheels 16 can facilitate movements of the test box 100.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A test box for electrostatic generators, comprising:
a housing structured to define a shielded space for receiving a measuring device and further structured to prevent outside electromagnetic radiation from entering the shielded space;
an electrostatic target mounted on an outside surface of the housing and electrically connected to the measuring device; wherein electrostatic signals emitted from the electrostatic generators are received and transmitted to the measuring device by the electrostatic target.

2. The test box as claimed in claim 1, wherein the housing includes a main body and a cover board; both the main body and the cover board made of electromagnetic shielding materials, the shielded space formed in the main body, and the cover board rotatably assembled to the main body for opening and closing of the shielded space.

3. The test box as claimed in claim 2, wherein the housing further includes a first gasket mounted in the main body and a second gasket mounted on the cover board; both the first gasket and the second gasket made of elastic materials, when the shielded space is closed by the cover board, the first gasket and the second gasket contact each other, such that impact generated between the main body and the cover board is decreased.

4. The test box as claimed in claim 3, wherein the second gasket is made of elastic electromagnetic shielding material; when the shielded space is closed by the cover board, the second gasket preventing outside electromagnetic radiation from entering the shielded space through an aperture between the main body and the cover board.

5. The test device as claimed in claim 2, wherein the housing further includes a shelf configured for holding of the measuring device and a number of protrusions formed in an inner surface of the main body for positioning of the shelf.

6. The test box as claimed in claim 5, wherein the protrusions are spaced at different heights within the main body.

7. The test box as claimed in claim 2, wherein the housing further comprises a detection member for viewing resultant waveforms from the electrostatic signals received by the measuring device; the detection member including a metal shield net and a transparent view window, the view window engaging with a hole defined in the main body, and the shield net mounted on the view window for preventing outside electromagnetic radiation from entering the shielded space through the view window.

8. The test box as claimed in claim 2, wherein the housing further includes a manual operation holder; the manual operation holder being a planar board mounted on the main body for placing a manual operation device for the measuring device.

9. The test box as claimed in claim 1, wherein the measuring device is an oscilloscope.
